(19) United States
(12) Patent Application Publication
(10) Pub. No.: US 2007/0141732 A1
(43) Pub. Date: Jun. 21, 2007

(54) Structural analysis method of deep trenches

(75) Inventors: Kuan-Hsun Huang, Ilan (TW); Jen-Lang Lue, Hsinchu City (TW)

Correspondence Address: BIRCH STEWART KOLASCH & BIRCH, PO BOX 747, FALLS CHURCH, VA, 22040-0747, US

(73) Assignee: ProMOS Technologies Inc.

(21) Appl. No.: 11/401,366

(22) Filed: Apr. 11, 2006

(30) Foreign Application Priority Data
Dec. 16, 2005 (TW) 94144855

(51) Int. Cl. H01L 21/66

(52) U.S. Cl. 438/14; 438/16

(57) ABSTRACT

A structural analysis method of deep trenches is provided. A substrate having a plurality of deep trenches is provided. A polishing process is performed on the substrate to form an incline in a partial region of the substrate to expose surface structures at different depths of the deep trenches. Then, a structural analysis of the surface structures at different depths of the deep trenches is performed to observe defects.

### RELATED APPLICATIONS

The present application is based on, and claims priority from, Taiwan Application Serial Number 94144855, filed Dec. 16, 2005, the disclosure of which is hereby incorporated by reference herein in its entirety.

### BACKGROUND

1. Field of Invention

The present invention relates to an inspection method of semiconductor circuit structures. More particularly, the present invention relates to a structural analysis method of deep trenches.

2. Description of Related Art

With increases in the density of semiconductor integrated circuits (IC), the sizes of semiconductor devices have been decreased. One method for densifying the integration of semiconductor integrated circuits in dynamic random access memory (DRAM) is to use trench capacitors. In order to increase the capacity of the capacitors, the trenches in the substrate should be made deeply. However, structural defects frequently occur while producing the trench capacitors, so that the quality of the semiconductor integrated circuits is adversely impacted.

A conventional structural analysis method for the trench capacitors is to use a focused ion beam (FIB) to gradually mill the overlying materials on the substrate and the upper portion materials in the substrate from the top to the bottom. An inspection using an electron microscope is performed on every exposed surface structure in a predetermined depth of the deep trenches after the removal of the materials. FIG. 1 is a cross-sectional diagram showing that the focused ion beam is used to partially remove the materials to expose surface structure of trenches at different depths. A plurality of deep trenches 102 are formed in a substrate 100. After removing portions of the deep trenches 102 to a first depth h₁, they are inspected. Next, portions of the deep trenches 102 in a second depth h₂ are removed and then inspected. The removal and inspection process is performed in sequence until inspections of the deep trenches in the substrate 100 are finished.

However, the problem of the conventional structural analysis method is that only a few structural defects in fixed depths, such as in the first depth h₁ or in the second depth h₂, can be inspected. If the structural defects occur elsewhere in the structure, they are not discovered by the removal and inspection process. Therefore, the conventional structural analysis method for the deep trenches is not convenient to be performed and the structural defects are difficult to be found exactly. Moreover, the conventional structural analysis method takes about 4 hours to inspect one sample with 16 um² exposed surface. If inspections of deep trenches at other depths are needed, even more time is necessary for inspection.

Thus, a structural analysis method of deep trenches at different depths is required to solve the problems mentioned above.

### SUMMARY

In one aspect, this present invention provides a structural analysis method of deep trenches to inspect surface structure at different depths.

In another aspect, this present invention provides a structural analysis method of deep trenches that can be performed quickly and exactly.

In yet another aspect, this present invention provides a structural analysis method of deep trenches that can inspect much larger inspection areas on a substrate.

In accordance with the foregoing and other aspects of the present invention, the present invention provides a structural analysis method of deep trenches comprising the following steps. First, a substrate having a plurality of deep trenches is positioned on a polishing holder. A polishing process is performed on the substrate having the deep trenches to form an incline on at least a partial region of the substrate, so that surface structures of the deep trenches are exposed at different depths. An angle between the incline and one plane surface of the substrate is preferably from 1° to 6°.

Then, a structural analysis of the surface structures is performed. The substrate is unloaded from the polishing holder, and then the incline of the substrate is washed by cleaning solution. After cleaning the incline of the substrate, a metal layer is deposited thereon. After that, an electron microscope, such as a scanning electron microscope, is used to inspect and perform structural analysis of the surface structures of the deep trenches exposed at different depths to observe the structural defects of the deep trenches.

According to a preferred embodiment of the present invention, a stage having a bevel is provided so that the substrate can be positioned on the bevel of the stage and then polished mechanically. An angle between the bevel of the stage and the horizontal plane is preferably from 1° to 6°. The angle can be adjusted according to the demands, such as using a larger angle for exposing the surface structure of the deep trenches with various depths in a shorter distance. When the substrate is placed on the stage, one side of the substrate is aligned with the upper edge of the stage, and the bottom plane surface of the substrate is adhered to the bevel of the stage. Thus, when the inclined substrate is polished horizontally, the polishing process actually makes the substrate to form an incline with an angle between the bottom plane surface of the substrate and the incline equal to the angle of the bevel of the stage.

After polishing, a structural analysis of the surface structures is performed to inspect structural defects of the deep trenches. The steps of the structural analysis of the deep trenches are preferably the same as those steps of the structural analysis of the deep trenches mentioned above, so the description relating to those steps is not repeated here.

In light of the foregoing, a structural analysis method of deep trenches can be operated quickly. The present invention provides a structural analysis method of deep trenches that can inspect much larger areas on the substrate. Moreover, surface structures of the deep trenches at different depths can be inspected in one polishing process. Thus, the method of the present invention has better precision of inspection for structural defects of the deep trenches to improve benefit.

The present invention is not only limited to the process applied to DRAM, but can be applied to any device of circuits having trench structures in a substrate to inspect the trench structures efficiently and quickly.

### BRIEF DESCRIPTION OF THE DRAWINGS

The invention can be more fully understood by the following detailed description of the preferred embodiment, with reference made to the accompanying drawings as follows:

FIG. 1 is a cross-sectional diagram showing that the focused ion beam is used to partially remove circuits to expose trenches at different depths.

FIG. 2 is a schematic diagram showing a substrate fixed on a stage according to one embodiment of the present invention.

FIG. 3 is a schematic diagram showing the substrate on the stage after being polished according to one embodiment of the present invention.

FIG. 4 is a schematic diagram along the I-I′ line of FIG. 3.

FIG. 5 is an electron microscope image showing the surface structures of the deep trenches at 4.5 um depths.

FIG. 6A to FIG. 6D are electron microscope images showing the surface structures of the deep trenches at different depths.

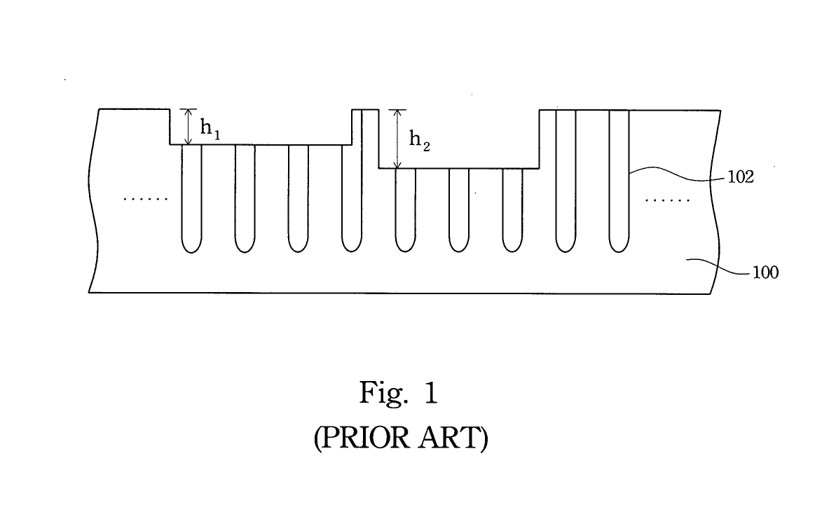

### DESCRIPTION OF THE PREFERRED EMBODIMENTS

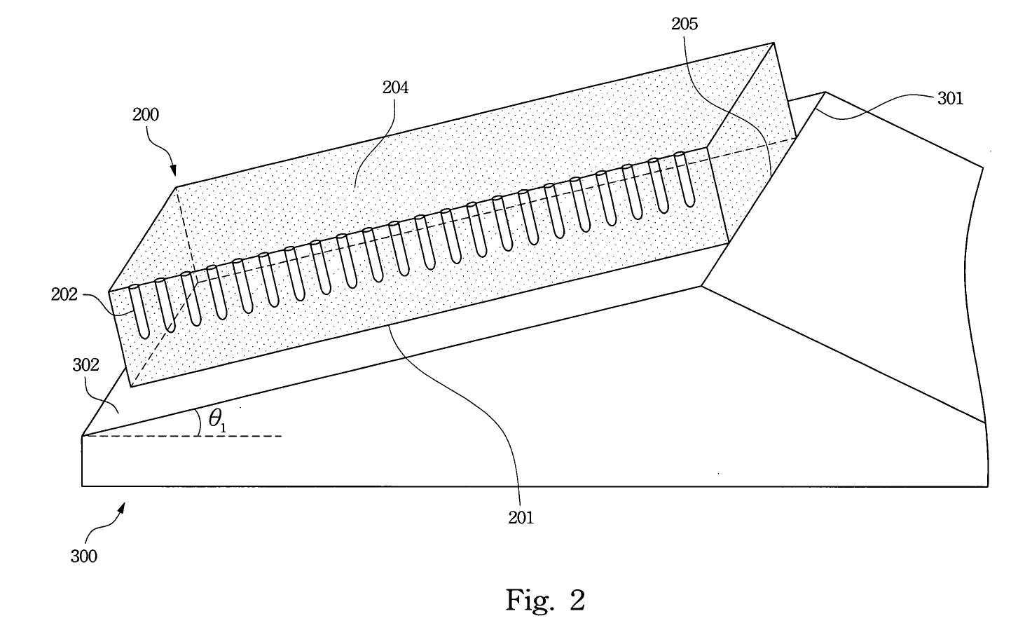

FIG. 2 is a schematic diagram showing a substrate fixed on a stage according to one embodiment of the present invention. In FIG. 2, a stage 300 having a bevel 302 and an upper edge 301 is provided. A substrate 200 comprises a side 205, an upper plane surface 204, a bottom plane surface 201 and a plurality of deep trenches 202. The substrate 200 is positioned on the stage 300, wherein the side 205 is aligned with the upper edge 301, and the bottom plane surface 201 is adhered to the bevel 302. The arrangement of deep trenches 202 in FIG. 2 is just an example and can't be used to limit the scope of the present invention.

There is a first angle θ₁ between the bevel 302 and the horizontal plane parallel with the bottom of the stage 300, wherein the first angle θ₁ is preferably from 1° to 6°. According to one embodiment of the invention, the first angle θ₁ is preferably 2° 52″. The substrate 200 is glued on the bevel 302 by an adhesive. The adhesive is preferably hot melt adhesive or paraffin wax.

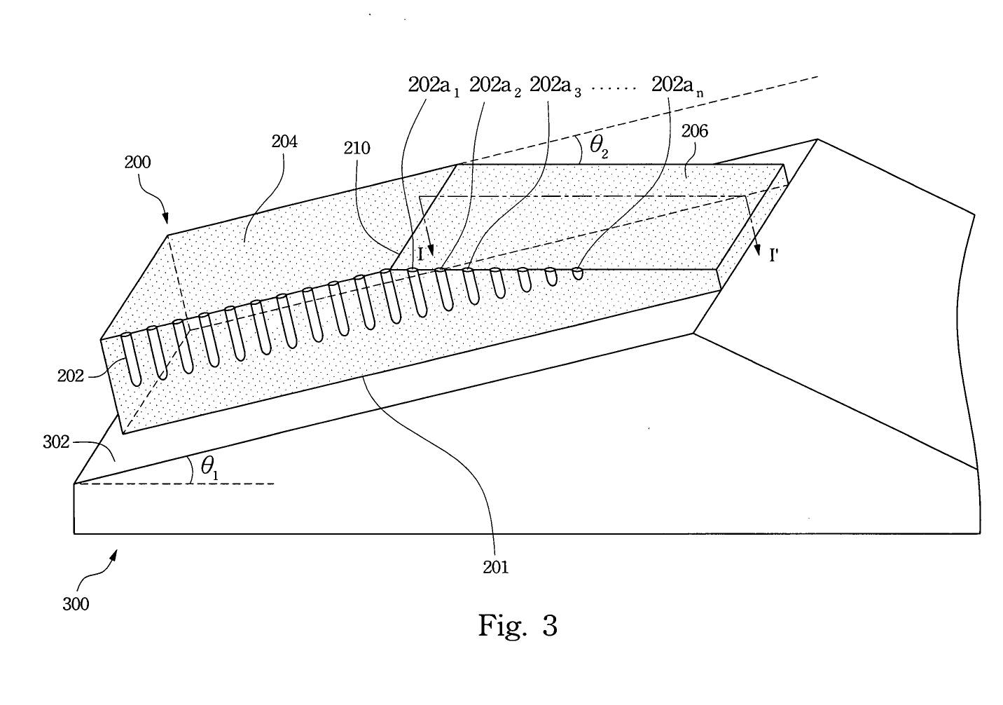

After that, a polishing process is performed. FIG. 3 is a schematic diagram showing the substrate on the stage that is polished according to one embodiment of the present invention. The stage 300 holding the substrate 200 is positioned on a polishing platform (not shown in FIG. 3). The upper plane surface 204 of the substrate 200 is polished to form an incline 206 by a polishing apparatus (not shown in FIG. 3) with polishing plane parallel to the bottom of the stage 300, so that surface structure 202a₁, 202a₂, . . . , 202aₙ of the deep trenches 202 at different depths are exposed. A line 210 divides the top surface of the substrate into the incline 206 and the upper plane surface 204 that has not been polished. There is a second angle θ₂ between the incline 206 and the bottom plane surface 201.

Since the substrate 200 is fixed on the bevel 302 of the stage 300, the incline 206 is polished almost parallel to the horizontal plane. According to one embodiment of the present invention, the second angle θ₂ between the incline 206 and the bottom plane surface 201 is equal to the first angle θ₁ between the bevel 302 and the horizontal plane, i.e. the second angle θ₂ between the incline 206 and the bottom plane surface 201 is determined by the inclined angle θ₁ of the bevel 302.

The material for performing the mechanical polishing process is preferably a slurry of diamond abrasive and lubricant. The diameter of the diamond abrasive is preferably 0.05 um.

Subsequently, a structural analysis of the surface structures 202a₁, 202a₂, . . . , 202aₙ is performed to inspect structural defects of the deep trenches. The substrate 200 and the stage 300 are removed from the polishing platform, and then the incline 206 of the substrate 200 is washed by cleaning solution. After cleaning the incline 206 of the substrate 200, a metal layer is deposited on the incline 206 of the substrate 200. The cleaning solution is preferably acetone and the material of the metal layer is preferably Au or Pt.

Then, the substrate 200 attached to the stage 300 is placed into an electron microscope, such as a scanning electron microscope, to inspect the surface structures 202a₁, 202a₂, . . . , 202aₙ of the deep trenches 202 at different depths to look for defects, such as abnormal configuration of the deep trenches or shorts among the surface structures 202a. The following description describes different inspection analysis methods according to one embodiment of the present invention.

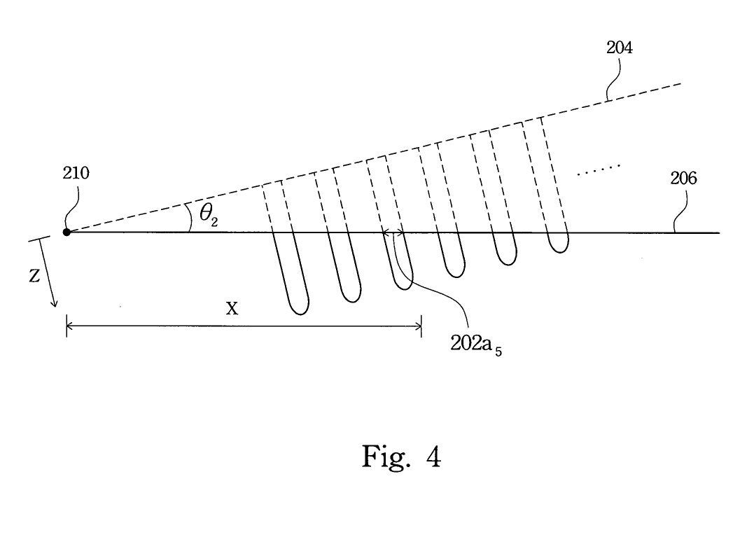

The structure produced by the method according to one embodiment of the present invention can allow inspecting the surface structure of the deep trenches at the specific inspection depths according to the demands. Alternatively, the depth of the structural defects can be determined by positions of the structural defects in the substrate found during performing the inspection. FIG. 4 is a schematic diagram along the I-I′ line of FIG. 3. In FIG. 4, the surface structure 202a₅ having a structural defect is found during the inspection. A depth Z of the surface structure 202a₅ is an unknown value. A distance X from the surface structure 202a₅ to the line 210 can be measured by the electron microscope. The second angle θ₂ is a known angle. Therefore, according to the trigonometric function (1) shown as the following formula:
Z=X sin θ₂ (1)
the depth Z of the surface structure 202a₅ can be calculated.

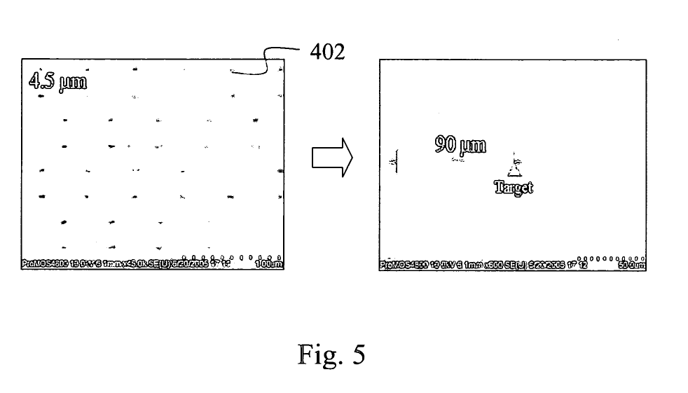

According to one embodiment of the present invention, the second angle θ₂ is 2° 41′. The value of sin θ₂ is about 0.05. The trigonometric function (1) is then rewritten as Z=0.05×, and the depth Z of the surface structure 202a₅ can be calculated easily while the distance X is given. The different second angle θ₂ can be used according to the demands. According to the embodiment of the present invention, the inspected surface structure 402 is a structural defect shown as FIG. 5 after the inspection analysis is performed. The structural defect may cause a short circuit between the surface structure 402 and its adjacency. Then, the position of the structural defects in the incline is measured and then the depth of the structural defects according to the trigonometric function (1) can be calculated.

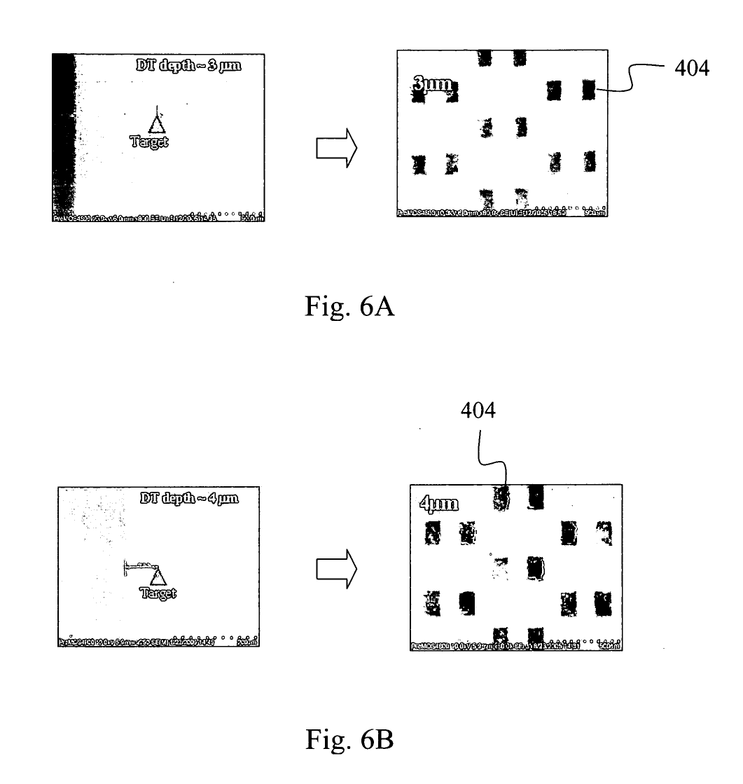

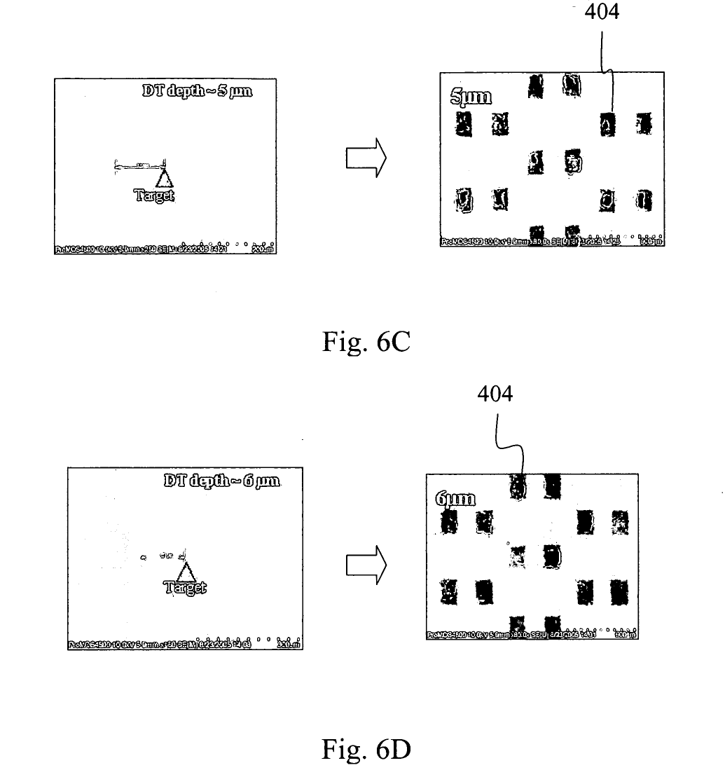

Alternatively, the surface structures at a specific depth are inspected directly to check whether the structural defects of the deep trenches exist. First, the specific depth Z of the surface structure of the deep trenches desired to be inspected is decided. After that, the distance X corresponding to the depth Z can be calculated according to the trigonometric function (1). Afterward, a laser marker is used to mark from the line 210 to the distance X at the specific position of the incline 206. The substrate 200 is placed into the electron microscope to find the laser mark. After the laser mark is found, the image of the deep trenches at the specific depth Z is obtained. FIG. 6A to FIG. 6D are electron images showing the deep trenches at different depths. In FIG. 6A, the surface structure 404 of the deep trenches is a normal structure, which is inspected at a 3 um depth. In FIG. 6B to FIG. 6D, the surface structures 404 of the deep trenches are normal, which are inspected at 4 um, 5 um, and 6 um depths respectively.

Thus, compared with the conventional methods, the present invention provides a structural analysis method of deep trenches to inspect surface structure at different depths. Moreover, surface structures of the deep trenches at different depths can be inspected in one polishing process. Furthermore, the method of the present invention has better precision of inspection for structural defects of the deep trenches to improve cost benefit, in which the inspection areas are about 9 mm² and a sample substrate produced according to the present invention needs about 3 hours for inspection. Therefore, the present invention can accomplish structural analysis quickly and efficiently. Besides, the present invention provides a structural analysis method of deep trenches that can inspect much larger areas on the substrate, so that surface structures at different depths are revealed in one polishing process.

The present invention is not only limited to DRAM deep trenches but can be applied to any device having trench structures in a substrate or on a substrate to inspect the trench structures efficiently and quickly.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A structural analysis method of deep trenches, comprising:
providing a substrate having a plurality of deep trenches;
performing a polishing process on the substrate to form an incline on at least a partial region of the substrate to expose surface structures of the deep trenches at different depths; and
inspecting the surface structures at different depths of the deep trenches to find structural defects.

2. The structural analysis method of deep trenches of claim 1, wherein an angle between the incline and a plane surface of the substrate is from 1° to 6°.

3. The structural analysis method of deep trenches of claim 1, wherein the polishing process is a mechanical polishing process.

4. The structural analysis method of deep trenches of claim 3, wherein material used for performing the mechanical polishing process is a slurry of diamond abrasive and lubricant.

5. The structural analysis method of deep trenches of claim 1, wherein the step of inspecting the surface structures comprises a step of using a scanning electron microscope.

6. A structural analysis method of deep trenches, comprising:
fixing a substrate on a bevel of a stage having an upper edge, wherein the substrate comprises a plane surface, a side, and a plurality of deep trenches;
performing a polishing process on the substrate to form an incline on at least a partial region of the substrate to expose surface structures of the deep trenches at different depths, wherein an angle between the incline and the plane surface of the substrate is from 1° to 6°; and
inspecting the surface structures of the deep trenches at different depths to find structural defects.

7. The structural analysis method of deep trenches of claim 6, wherein the polishing process is a mechanical polishing process.

8. The structural analysis method of deep trenches of claim 7, wherein a material used for performing the mechanical polishing process is a slurry of diamond abrasive and lubricant.

9. The structural analysis method of deep trenches of claim 6, wherein the step of inspecting the surface structures comprises a step of using a scanning electron microscope.

10. The structural analysis method of deep trenches of claim 6, wherein the side of the substrate is aligned with the upper edge of the bevel of the stage.
